(19) United States
(12) Patent Application Publication
(10) Pub. No.: US 2005/0158932 A1
(43) Pub. Date: Jul. 21, 2005

(54) Method of manufacturing semiconductor device

(76) Inventors: Seiji Inumiya, Ibaraki (JP); Akio Kaneko, Kanagawa (JP); Motoyuki Sato, Kanagawa (JP); Katsuyuki Sekine, Kanagawa (JP); Kazuhiro Eguchi, Kanagawa (JP); Yoshitaka Tsunashima, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/995,296

(22) Filed: Nov. 24, 2004

(30) Foreign Application Priority Data
Nov. 26, 2003 (JP) 2003-395307

(51) Int. Cl. H01L 21/336; H01L 21/8234; H01L 21/31

(52) U.S. Cl. 438/197; 438/591; 438/766; 438/769

(57) ABSTRACT

A method of manufacturing a semiconductor device, comprises: providing a gate insulation layer of a high dielectric constant containing a metal element on a surface of a semiconductor substrate, part of which becoming a channel; providing a first conductive layer containing a silicon element on the surface of said gate insulation layer, said first conductive layer being a gate electrode; and introducing nitrogen or oxygen onto an interface between said gate insulation layer and said first conductive layer by executing a thermal treatment upon said semiconductor substrate in a atmosphere containing a nitriding agent or an oxidizing agent.

### CROSS REFERENCE TO RELATED APPLICATIONS

This application is based upon and claims the benefit of priority from the prior Japanese Patent Application No.2003-395307, filed on Nov. 26, 2003: the entire contents of which are incorporated herein by reference.

### BACKGROUND OF THE INVENTION

This invention generally relates to a semiconductor device, and more particularly to a process of forming a high dielectric gate insulation layer.

As the semiconductor device such as a MOS (Metal-Oxide Semiconductor) transistor, etc. is miniaturized, a silicon oxide layer or a silicon oxy-nitride layer, which has hitherto been used as a gate insulation layer, confronts with a limit of a layer-thinning (thin-film) scheme. This is derived from such a situation that an increase in consumption of the electric power due to a rise in direct tunneling leakage current comes to an unallowable level.

A technology applied to a gate insulation layer composed of a high dielectric layer having a higher dielectric constant than that of a silicon oxide layer, is proposed as a method of restraining this leakage current. Prior arts using the high dielectric constant insulation layer are disclosed in Japanese Patent Application Publication NOs.2003-25824, 2003-204061 and 2003-8011.

If the insulation layer exhibiting the higher dielectric constant than the silicon oxide layer is employed, the insulation layer that is thicker than the silicon oxide layer can be used, and, as a result, there decreases a necessity for concern about the rise in tunneling leakage current. Among those materials, hafnium silicate (HfSiO) and hafnium silicon oxynitride (HfSiON) are considered to be most prospective candidate materials capable of actualizing a proper specific dielectric constant, preferable thermal stability and a preferable interface characteristic.

Japanese Patent Application Laid-Open (Unexamined) Publication No.2003-25824 discloses a technology capable of keeping low an interface level density on an interface between a gate insulation layer and a semiconductor substrate so as to have a region where the gate insulation layer using a high dielectric material is nitrided. Japanese Patent Application Laid-Open Publication No.2003-204061 discloses a technology characterized such that a silicon oxide layer containing a metal element, which structures a gate insulation layer 14 shown in FIG. 5, includes a first region in the vicinity of an undersurface, a second region in the vicinity of an upper surface and a third region between the first region and the second region, and a concentration distribution in a thicknesswise direction of the metal element contained in the silicon oxide layer has a maximum point in the third region. Japanese Patent Application Laid-Open Publication No.2003-8011 discloses such a technology that the gate insulation layer shown in FIG. 1 has at least any one of a high dielectric layer containing one metal composed of Hf or Zr, oxygen and silicon, a lower barrier layer formed under the high dielectric layer and an upper barrier layer formed above the high dielectric layer, the lower barrier layer prevents reaction between the high dielectric layer and a substrate and increases a specific dielectric constant of the whole gate insulation layer, and the upper barrier layer prevents mutual diffusion of a material of the gate electrode mater and a material of the high dielectric layer, and increases a specific dielectric constant of the whole gate insulation layer.

If the dielectric layer such as a hafnium silicate layer having a high dielectric constant is applied to a process of a conventional semiconductor device (MOS transistor) using a polycrystalline silicon layer or a polycrystalline silicon/germanium layer as a gate electrode, however, there arises a problem, wherein an abnormal shift of a flat band voltage occurs, and a low threshold voltage indispensable for increasing performance can not be obtained. For embodiment, as shown in FIG. 4, the flat band voltage shifts by +0.2 V when the MOS transistor (nMOSFET) is manufactured based on the conventional method by use of a high dielectric constant insulation layer composed of hafnium silicate as a gate electrode containing silicon, and it is difficult to realize the low threshold value needed for the high performance (the flat band voltage shifts by −0.6 V in the case of pMOSFET).

### SUMMARY OF THE INVENTION

According to an aspect of the present invention, there is provided a method of manufacturing a semiconductor device, comprising:
providing a gate insulation layer of a high dielectric constant containing a metal element on a surface of a semiconductor substrate, a part of which becoming a channel;
providing a first conductive layer containing a silicon element on the surface of said gate insulation layer, said first conductive layer being a gate electrode; and
introducing nitrogen or oxygen onto an interface between said gate insulation layer and said first conductive layer by executing a thermal treatment upon said semiconductor substrate in a atmosphere containing a nitriding agent or an oxidizing agent.

According to another aspect of the present invention, there is provided a method of manufacturing a semiconductor device, comprising:
providing a gate insulation layer of a high dielectric constant containing a metal element on the surface of a semiconductor substrate, a part of which becoming a channel;
providing a first conductive layer containing a silicon element on the surface of said gate insulation layer, said first conductive layer being a gate electrode;
introducing any one of nitrogen, oxygen, fluorine and carbon into said first conductive layer; and
diffusing any one of nitrogen, oxygen, fluorine and carbon introduced into said conductive layer, over an interface between said gate insulation layer and said conductive layer by executing a thermal treatment upon said semiconductor substrate.

### BRIEF DESCRIPTION OF THE DRAWINGS

FIG. 1 is an explanatory process sectional view showing a method of manufacturing a semiconductor device according to a first embodiment of the present invention;

FIG. 2 is an explanatory process sectional view showing the method of manufacturing the semiconductor device according to the first embodiment of the present invention;

FIG. 3 is an explanatory process sectional view showing the method of manufacturing the semiconductor device according to the first embodiment of the present invention;

FIG. 4 is a characteristic diagram showing a C-V characteristic of a MOS transistor manufactured by processes shown in FIGS. 1 through 3;

FIG. 5 is an explanatory process sectional view showing the method of manufacturing the semiconductor device according to a second embodiment of the present invention;

FIG. 6 is an explanatory sectional view of a semiconductor substrate, showing a MOS type transistor manufactured by the manufacturing method in FIG. 5;

FIG. 7 is a schematic view showing a profile of nitrogen in a polycrystalline silicon layer in the semiconductor device manufacturing method according to a third embodiment of the present invention; and

FIG. 8 is an explanatory process sectional view showing a method of manufacturing the semiconductor device manufacturing method according to the third embodiment of the present invention.

### DETAILED DESCRIPTION

The present invention attains an acquisition of a high-performance semiconductor device capable of actualizing a low threshold voltage by obtaining the same level of flat band voltage as in the case of using a silicon oxide layer by way of a gate insulation layer, wherein a defect formed on an interface between a gate electrode composed of a polycrystalline silicon (or silicon and germanium) layer and a higher dielectric constant gate insulation layer containing a metal element is repaired by any one of a nitride layer, an oxide layer, a fluoride layer and a carbide layer that are formed of a nitriding agent, an oxidizing agent, a fluorinating agent and a carbonizing agent supplied via electrodes, with the result that a shift of a flat band voltage is reduced.

Embodiments of the present invention will hereinafter be discussed with reference to practical embodiments.

(Embodiment 1)

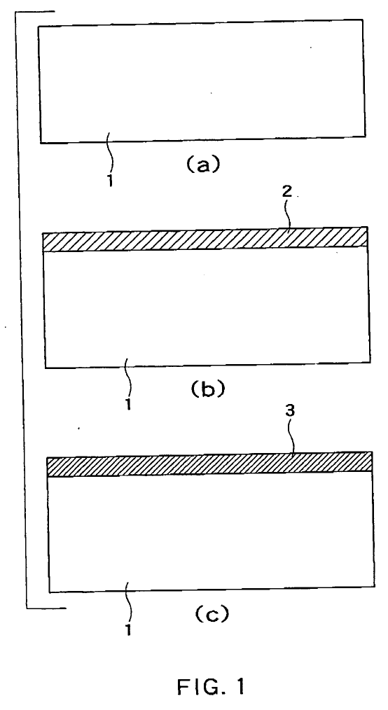

To start with, an embodiment 1 will be described with reference to FIGS. 1 through 4

FIGS. 1 through 3 are explanatory sectional views showing a process of manufacturing a semiconductor device. FIG. 4 is a characteristic diagram showing a C-V characteristic of the semiconductor device (nMOSFET) manufactured in the process shown in FIG. 1. The embodiment 1 exemplifies how nitrogen is introduced onto the interface between the high dielectric gate insulation layer and the gate electrode by utilizing a thermal treatment. A device isolation region (unillustrated) such as STI (Shallow Trench Isolation), etc. is provided by a normal method on a semiconductor substrate 1 (e.g., a p-type silicon, semiconductor), and channel impurity ions are implanted (not shown) for adjusting a threshold voltage. The surface of a device forming region on this semiconductor substrate 1 is exposed by cleaning with diluted hydrofluoric acid (FIG. 1(a)). Next, a hafnium silicate (HfSiO) layer 2 is deposited by approximately 2 nm, which involves using a MOCVD (Metal Organic Chemical Vapor Deposition) method. Then, a thermal treatment is immediately effected in an O₂ atmosphere under 10 Torr for 2 min., thereby removing residual impurities in the layer (FIG. 1(b)).

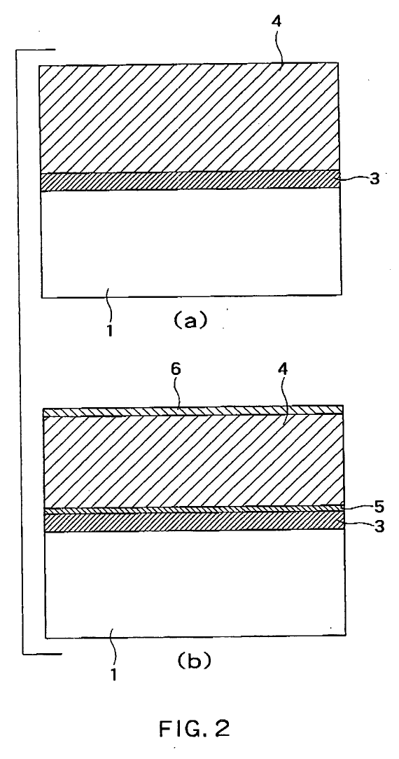

Subsequently, the hafnium silicate layer 2 is exposed to plasma using an Ar/N₂ gas, nitrogen is introduced from the surface of the hafnium silicate layer 2, and immediately the thermal treatment is conducted at 1000° C. in an atmosphere of 5 mTorr as an oxygen partial pressure for 10 sec., thus stabilizing the nitrogen atoms introduced. A quality of shift of the flat band voltage changes depending on a quantity of introduced nitrogen. Accordingly, the introduction quantity is determined to become a value required for reducing the shift quantity. A hafnium silicon oxynitride (HfSiON) layer 3 is thus provided on the semiconductor substrate 1 (FIG. 1(c)). Next, a polycrystalline silicon layer 4 serving as a gate electrode is deposited by 100 nm by use of a LPCVD (Low Pressure Chemical Vapor Deposition) method (FIG. 2(a)). Subsequently, the thermal treatment is executed at 950° C. in a NO gas in an atmosphere of 200 Torr for 30 min.

With this thermal treatment executed, an interface nitride layer 5 is provided on an interface between the polycrystalline silicon layer 4 and the hafnium silicon oxynitride layer 3, and an oxy-nitride layer 6 is provided on the surface of the polycrystalline silicon layer 4. At this time, nitrogen with a surface density that is on the order of 5E+14 atoms/cm² is introduced into the interface nitride layer 5.

An interface layer thickness at this time is approximately 1 Å (angstrom). A better state is obtained as the interface layer becomes thinner, and this thickness (approximately 1 Å) is most appropriate (See FIG. 2(b))

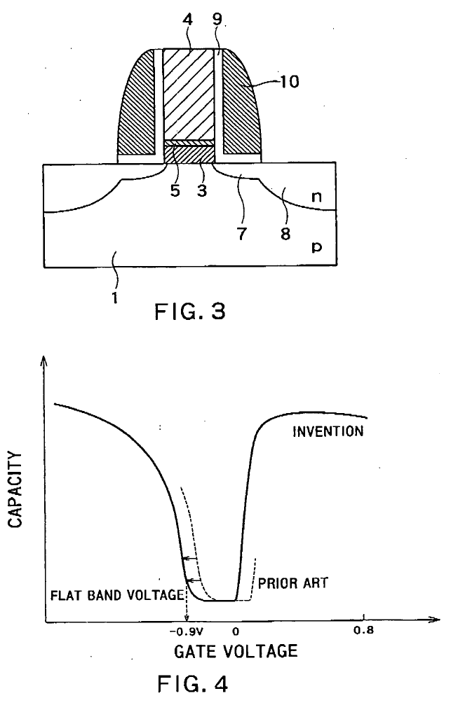

Hereinafter, based on, though not shown, a normal method, the stacked layers consisting of the hafnium silicon oxynitride layer 3, the interface nitride layer 5 and the polycrystalline silicon layer 4 are subjected to patterning by use of a photo-resist having undergone the patterning, thereby building up a gate structure. With this gate structure used as a mask, n-type impurities such as phosphorus, arsenic, etc. are ion-implanted into the semiconductor substrate 1, and thermal diffusion takes place, thereby forming an extension region 7 in the vicinity of the gate structure. Thereafter, a side-wall insulation layer 9 formed of a silicon oxide layer and a side-wall insulation layer 10 formed of a silicon nitride layer are provided along a gate-structured side wall. After this, with the gate structure and the side-wall insulation layers 9, 10 used as a mask, the n-type impurities such as phosphorus, arsenic, etc. are ion-implanted deep into the semiconductor substrate 1, and the thermal diffusion is performed, thereby forming a source/drain region 8 in a position deeper than the extension region 7 (FIG. 3). A basic structure of the MOS type transistor (nMOS) is thus configured. Further, a semiconductor integrated circuit is constructed through a multi-layered wiring (interconnection) process.

The MOS type transistor constructed by the method described above exhibits the same level of flat band voltage as in the case of using the silicon oxide layer as the gate insulation layer (FIG. 4). Namely, in the embodiment 1, the shift of the flat band voltage, which might occur in the transistor including the gate insulation layer composed of the high dielectric constant material that has been manufactured by the conventional method, is restrained to such a degree as not to affect the transistor characteristic. Accordingly, a low reversal threshold voltage (approximately 0.1 V) is obtained, and a sufficiently high ON-current is acquired at a power source voltage of 1.2 V. This is, it is considered, because the defect formed on the interface between the polycrystalline silicon layer 4 and the hafnium silicon oxynitride layer 3 was repaired by nitriding of the nitriding agent supplied via the gate electrode. Even when the nitriding agent is supplied onto the hafnium silicate layer without through the gate electrode, the nitriding advances into an interior, and the nitride layer is not formed on the interface between the gate electrode and the hafnium silicate layer that will be provided thereafter. It is therefore difficult to prevent the shift of the flat band voltage.

Moreover, the embodiment 1 has given the exemplification, wherein the mono-crystalline silicon semiconductor substrate is employed for the region that becomes a channel, however, the present invention is not limited to the silicon semiconductor substrate and the same effects are acquired even when using SOI, SiGe, distorted Si and so on. Further, the embodiment 1 involves using the hafnium silicate layer deposited by the MOCVD method, however, the present invention is not limited to either the deposition method thereof or the insulation layer material and the same effects are acquired even in the case of employing a HfO₂ layer, a hafnium aluminate layer, etc. which are formed by an ALD (Atomic Layer Deposition) method and so forth. Moreover, the case of using the polycrystalline silicon layer as the gate electrode has been exemplified, however, the same effects are acquired in the case of employing a polycrystalline silicon germanium layer and a silicide (WSi, NiSi, etc.) layer as the gate electrode. The reason for this is that an abnormal shift of the flat band voltage occurs due to interaction between the metal element of hafnium (Hf), etc. in the insulation layer and a silicon element in the electrode. Further, the embodiment 1 involves the use of the NO gas as the nitriding gas defined as the nitriding agent, however, the same effects can be obtained even when employing N₂O, NH₃, ND₃, nitrogen radical, etc..

Still further, in the embodiment 1, the polycrystalline silicon layer serving as the gate electrode is deposited by 100 nm, and the interface nitriding is effected over this layer of 100 nm. However, a silicon layer that is as thin as 20 nm is once formed, and the interface nitriding may also be conducted through this thin silicon layer. If the nitriding is thus effected over the thin silicon layer, the same quantity of interface nitriding can be obtained by the thermal treatment lighter than through a thick silicon layer. This reduces a thermal damage to the high dielectric gate insulation layer, thereby improving reliability. Note that the nitriding effected over the thin silicon layer requires a process of removing the oxy-nitride layer formed simultaneously on the surface by use of a diluted hydrofluoric acid solution, etc. and thereafter attaining a desired layer thickness by additionally depositing the polycrystalline silicon layer.

(Embodiment 2)

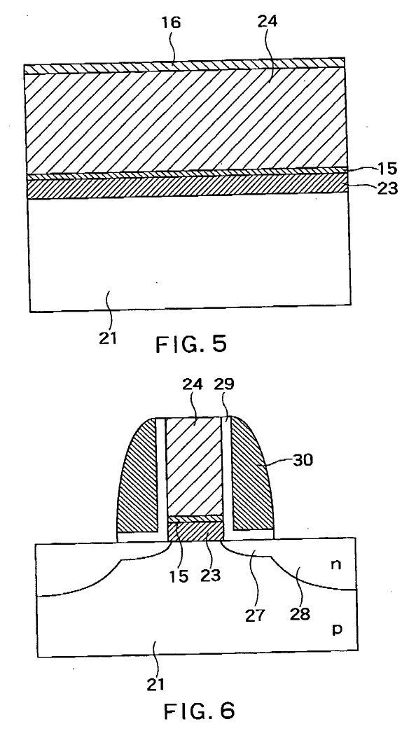

Next, an embodiment 2 will be explained with reference to FIGS. 5 and 6.

FIG. 5 is an explanatory process sectional view showing a method of manufacturing the semiconductor device (MOS type transistor). FIG. 6 is an explanatory sectional view of a semiconductor substrate, showing the MOS type transistor manufactured by the manufacturing method in FIG. 5. The embodiment 2 exemplifies how oxygen is introduced by a thermal treatment in an oxidative atmosphere onto an interface between a gate insulation layer composed of a high dielectric constant material and a gate electrode. The process is the same as in the embodiment 1 till the hafnium silicon oxynitride layer is provided, and hence the illustrations of the components corresponding to those in FIGS. 1 through 2(a) are omitted.

A device isolation region (unillustrated) such as STI, etc. is provided by the normal method on a semiconductor substrate 21 (e.g., a p-type silicon semiconductor), and channel impurity ions are implanted (not shown) for adjusting the threshold voltage. The surface of a device forming region on this semiconductor substrate 21 is exposed by cleaning with the diluted hydrofluoric acid. Next, a hafnium silicate (HfSiO) layer (unillustrated) is deposited by approximately 2 nm, which involves using the MOCVD method. Then, the thermal treatment is immediately effected in the O₂ atmosphere under 10 Torr for 2 min., thereby removing residual impurities in the layer. Subsequently, the hafnium silicate layer is exposed to plasma using the Ar/N₂ gas, nitrogen is introduced from the surface of the hafnium silicate layer, and immediately the thermal treatment is conducted at 1000° C. in an atmosphere of 5 m Torr as an oxygen partial pressure for 10 sec., thus stabilizing the nitrogen atoms introduced. A hafnium silicon oxynitride (HfSiON) layer 23 is thus provided on the semiconductor substrate 21.

Next, a polycrystalline silicon layer 24 serving as a gate electrode is deposited by 100 nm by use of the LPCVD method. Subsequently, the thermal treatment is executed at 950° C. in the O₂ gas in an atmosphere of 50 Torr for 30 min. With this thermal treatment executed, an interface nitride layer 15 is provided on an interface between the polycrystalline silicon layer 24 and the hafnium silicon oxynitride layer 23, and a silicon oxide layer 16 is provided on the surface of the polycrystalline silicon layer 24. At this time, oxygen with a surface density thereof is on the order of 1E+14 atoms/cm₂ is introduced into the interface oxide layer 15.

Hereinafter, based on, though not shown, the normal method, the stacked layers consisting of the hafnium silicon oxynitride layer 23, the interface oxide layer 15 and the polycrystalline silicon layer 24 are subjected to the patterning by use of the photo-resist having undergone the patterning, thereby building up a gate structure. With this gate structure used as a mask, n-type impurities such as phosphorus, arsenic, etc. are ion-implanted into the semiconductor substrate 21, and the thermal diffusion takes place, thereby forming an extension region 27 in the vicinity of the gate structure. Thereafter, a side-wall insulation layer 29 formed of a silicon oxide layer and a side-wall insulation layer 30 formed of a silicon nitride layer are provided along a gate-structured side wall.

Then, with the gate structure and the side-wall insulation layers 29, 30 used as a mask, the n-type impurities such as phosphorus, arsenic, etc. are deeply ion-implanted into the semiconductor substrate 21, and the thermal diffusion is performed, thereby forming a source/drain region 28 in a position deeper than the extension region 27. A basic structure of the MOS type transistor (nMOS) is thus configured. Further, a semiconductor integrated circuit is thus constructed through the multi-layered wiring process.

The MOS type transistor constructed by the method described above exhibits the same level of flat band voltage as in the case of using the silicon oxide layer as the gate insulation layer (see FIG. 4). Namely, as in the preceding embodiment, the shift of the flat band voltage, which might occur in the transistor including the gate insulation layer composed of the high dielectric material that has been manufactured by the conventional method, is restrained to such a degree as not to affect the transistor characteristic.

Accordingly, the low inverted threshold voltage (approximately 0.1 V) is obtained, and the sufficiently high ON-current is acquired at the power source voltage of 1.2 V. This is, it is considered, because the defect formed on the interface between the polycrystalline silicon layer and the hafnium silicon oxynitride layer was repaired by nitriding of the nitriding agent supplied via the gate electrode.

Moreover, the embodiment 2 has given the exemplification, wherein the mono-crystalline silicon semiconductor substrate is employed for the region that becomes a channel, however, the present invention is not limited to the silicon semiconductor substrate and the same effects are acquired even when using SOI, SiGe, distorted Si and so on. Further, the embodiment 2 involves using the hafnium silicate layer deposited by the MOCVD method, however, the present invention is not limited to either the deposition method thereof or the insulation layer material and acquires the same effects even in the case of employing a HfO₂ layer, a hafnium aluminate layer, etc. which are formed by the ALD method and so forth. Moreover, the case of using the polycrystalline silicon layer as the gate electrode has been exemplified, however, the same effects are acquired in the case of employing the polycrystalline silicon germanium layer or the silicide (WSi, NiSi, etc.) layer as the gate electrode. The reason for this is that the abnormal shift of the flat band voltage occurs due to the interaction between the metal element of hafnium (Hf), etc. in the insulation layer and the silicon element in the electrode. Further, the embodiment 2 involves the use of the O₂ gas as the oxidative gas, however, the same effects can be obtained even when employing O₃, H₂O, D₂O, oxygen radical, etc..

Still further, in the embodiment 2, the polycrystalline silicon layer serving as the gate electrode is deposited by 100 nm, and the interface oxidation is effected over this layer of 100 nm. However, a silicon layer that is as thin as 20 nm is once formed, and the interface oxidation may also be conducted through this thin silicon layer. If the oxidation is thus effected over the thin silicon layer, the same quantity of interface oxidation can be actualized by the thermal treatment lighter than through a thick silicon layer. This reduces a thermal damage to the high dielectric gate insulation layer, thereby improving the reliability. Note that the oxidation effected over the thin silicon layer requires a process of removing the oxide layer formed simultaneously on the surface by use of the diluted hydrofluoric acid solution, etc. and thereafter attaining a desired layer thickness by additionally depositing the polycrystalline silicon layer.

(Embodiment 3)

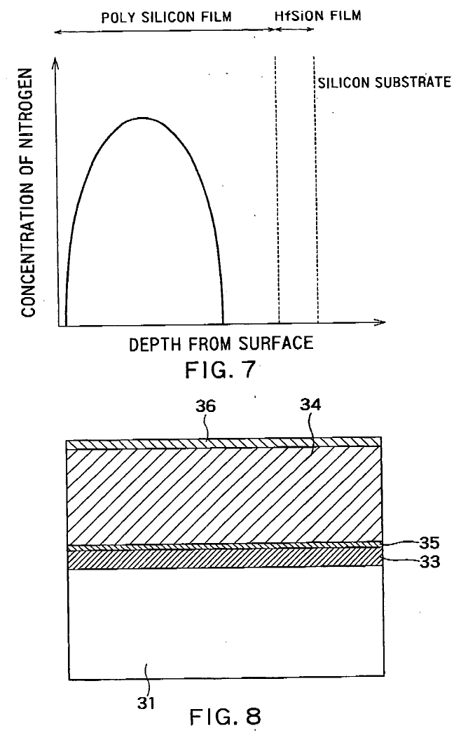

Next, an embodiment 3 will be explained with reference to FIGS. 7 and 8.

FIG. 7 is a schematic view showing a profile of nitrogen in the polycrystalline silicon layer in the embodiment 3. FIG. 8 is an explanatory process sectional view showing a method of manufacturing the semiconductor device in the embodiment 3. The embodiment 3 exemplifies how nitrogen is introduced by a diffusion method using the ion implantation of nitrogen into the gate electrode and the thermal treatment onto an interface between a gate insulation layer composed of a high dielectric constant material and a gate electrode.

To begin with, a MOS structure (see FIG. 8) using the hafnium silicon oxynitride layer is configured by the same method as in the embodiments 1 and 2.

A device isolation region such as STI, etc. is, though not illustrated, provided by the normal method on a semiconductor substrate 31 (e.g., a p-type silicon semiconductor), and channel impurity ions are implanted (not shown) for adjusting the threshold voltage. The surface of a device forming region on this semiconductor substrate 31 is exposed by cleaning with the diluted hydrofluoric acid. A hafnium silicon oxynitride (HfSiON) layer 33 is provided on this semiconductor substrate 31. Next, a polycrystalline silicon layer 34 serving as a gate electrode is deposited by 100 nm by use of the LPCVD method.

Subsequently, as shown in FIG. 7, nitrogen 32 with a surface density that is on the order of 5E+15 cm⁻² is introduced to have a peak into the polycrystalline silicon layer 34. Next, the thermal treatment is conducted at 850° C. in a N₂ gas in an atmosphere of normal atmospheric pressure for 30 min, thereby diffusing nitrogen introduced. Then an interface nitride later 35 is provided on an interface between the polycrystalline silicon layer 34 and the hafnium silicon oxynitride layer 32, and an oxy-nitride layer 36 is provided on the surface of the polycrystalline silicon layer 34. At this time, nitrogen with a surface density that is on the order of 5E+14 atoms/cm² is introduced into the interface nitride layer 35.

Thereafter, the patterning is effected on the gate electrode, the impurities are introduced into the gate electrode/source/drain region, and the side-wall insulation layer is formed by use of the normal conventional methods, thereby configuring the basic structure of the MOS type transistor. Further, the semiconductor integrated circuit is constructed through the multi-layered wiring process.

As described above, the thus-constructed MOS type transistor exhibits the same level of flat band voltage as in the embodiment 1 of using the silicon oxide layer as the gate insulation layer. Accordingly, the low reversal threshold voltage (approximately 0.1 V) is obtained, and the sufficiently high ON-current is acquired at the power source voltage of 1.2 V. This is, it is considered, because the defect formed on the interface between the polycrystalline silicon layer and the hafnium silicon oxynitride layer was repaired by nitriding of the nitriding agent diffused and supplied from the gate electrode.

Further, in the embodiment 3, the interface nitride layer is provided by ion-implanting and diffusing nitrogen, however, the present invention acquires the same effects even by implanting and diffusing oxygen, fluorine and carbon in place of nitrogen. In the case of using fluorine, the insulating characteristic can be improved, and, in the case of employing carbon, this serves to restrain the diffusion of the impurities.

The embodiment 3 has given the exemplification, wherein the mono-crystalline silicon semiconductor substrate is employed for the region that becomes a channel, however, the present invention is not limited to the silicon semiconductor substrate and acquires the same effects even when using SOI, SiGe, distorted Si and so on. Further, the embodiment 3 involves using the hafnium silicate layer deposited by the MOCVD method, however, the present invention is likewise limited to neither the deposition method thereof nor the insulation layer material and acquires the same effects even in the case of employing the HfO₂ layer, the hafnium aluminate layer, etc. which are formed by the ALD method and so forth. Moreover, the case of using the polycrystalline silicon layer as the gate electrode has been exemplified, however, the same effects are acquired in the case of employing the polycrystalline silicon germanium layer and the silicide (WSi, NiSi, etc.) layer as the gate electrode. The reason for this is that the abnormal shift of the flat band voltage occurs due to the interaction between the metal element of hafnium, etc. in the insulation layer and the silicon element in the electrode.

The embodiments given so far are the exemplifications but are not restrictive. The present invention can be modified in whatever forms within the scope that does not deviate from the gist of the invention. Further, the embodiments have exemplified the nMOSFET, however, it is apparent that the present invention can be applied to a pMOSFET, CMOSFET and so forth.

According to the present invention, the nitriding agent involves using a reactive gas such as a NO gas, N₂ gas, NH₃ gas, ND₃ gas and nitrogen radical. Moreover, according to the present invention, the oxidizing agent involves employing a gas such as an O₂ gas, an O₃ gas, an H₂ gas, a D₂ gas and oxygen radical. Still further, according to the present invention, the metal element involves the use of at least one type of element selected from, for embodiment, Hf, Zr, Al, La, Li, Be, Mg, Ca, Sr, Sc, Y, Th, U, Pr, Nd.

According to embodiments of the present invention, a manufacturing method for obtaining a semiconductor device capable of restraining an abnormal shift of a flat band voltage, exhibiting high performance and decreasing consumption of electric power in a MOS transistor using a high dielectric constant insulation layer such as a hafnium silicate layer as a gate insulation layer and using a polycrystalline silicon (or silicon/germanium) layer as a gate electrode is obtained.

According to the present invention, the constructions given above also lead to the acquisition of the high-performance semiconductor device capable of obtaining the same level of flat band voltage as in the case of using the silicon oxide layer as the gate insulation layer by reducing the shift of the flat band voltage, and capable of actualizing the low threshold voltage.

1. A method of manufacturing a semiconductor device, comprising:
providing a gate insulation layer of a high dielectric constant containing a metal element on a surface of a semiconductor substrate, part of which becoming a channel;
providing a first conductive layer containing a silicon element on the surface of said gate insulation layer, said first conductive layer being a gate electrode; and
introducing nitrogen or oxygen onto an interface between said gate insulation layer and said first conductive layer by executing a thermal treatment upon said semiconductor substrate in a atmosphere containing a nitriding agent or an oxidizing agent.

2. The method of manufacturing a semiconductor device according to claim 1, further comprising:
providing a second conductive layer containing a silicon element on the surface of said first conductive layer after introducing nitrogen or oxygen onto said interface, and forming a gate electrode by use of said first and second conductive layers.

3. The method of manufacturing a semiconductor device according to claim 1, wherein said nitriding agent is selected from a NO gas, N₂O gas, NH₃ gas, ND₃ gas or nitrogen radical.

4. The method of manufacturing a semiconductor device according to claim 1, wherein said oxidizing agent is selected from an O₂ gas, an O₃ gas, an H₂O gas, a D₂O gas or oxygen radical.

5. The method of manufacturing a semiconductor device according to claim 1, wherein said metal element is selected from Hf, Zr, Al, La, Li, Be, Mg, Ca, Sr, Sc, Y, Th, U, Pr or Nd.

6. A method of manufacturing a semiconductor device, comprising:
providing a gate insulation layer of a high dielectric constant containing a metal element on the surface of a semiconductor substrate, which becomes a channel;
providing a first conductive layer containing a silicon element on the surface of said gate insulation layer, said first conductive layer being a gate electrode;
introducing any one of nitrogen, oxygen, fluorine and carbon into said first conductive layer; and
diffusing any one of nitrogen, oxygen, fluorine and carbon introduced into said conductive layer, over an interface between said gate insulation layer and said conductive layer by executing a thermal treatment upon said semiconductor substrate.

7. The method of manufacturing a semiconductor device according to claim 3, further comprising:
providing a second conductive layer containing a silicon element on the surface of said first conductive layer after diffusing any one of nitrogen, oxygen, fluorine and carbon introduced into said conductive layer; and forming a gate electrode by use of said first and second conductive layers.

8. The method of manufacturing a semiconductor device according to claim 1, wherein said oxidizing agent is selected from an O₂ gas, an O₃ gas, an H₂O gas, a D₂O gas or oxygen radical.

9. The method of manufacturing a semiconductor device according to claim 1, wherein said metal element is selected from Hf, Zr, Al, La, Li, Be, Mg, Ca, Sr, Sc, Y, Th, U, Pr or Nd.

10. The method of manufacturing a semiconductor device according to claim 4, wherein said metal element is selected from a group consisting of Hf, Zr, Al, La, Li, Be, Mg, Ca, Sr, Sc, Y, Th, U, Pr, Nd.
